(19) United States
(12) Patent Application Publication
(10) Pub. No.: US 2009/0023268 A1
(43) Pub. Date: Jan. 22, 2009

(54) ISOLATION METHOD OF ACTIVE AREA FOR SEMICONDUCTOR DEVICE

(75) Inventors: Hsiao-Che WU, Chung-Li City (TW); Ming-Yen Li, Fongshan City (TW); Wen-Li Tsai, Renwu Township (TW)

Correspondence Address: Muncy, Geissler, Olds & Lowe, PLLC, P.O. BOX 1364, FAIRFAX, VA, 22038-1364, US

(73) Assignee: ProMos Technologies Inc.

(21) Appl. No.: 12/108,306

(22) Filed: Apr. 23, 2008

(30) Foreign Application Priority Data
Jul. 19, 2007 (TW) 96126421

(51) Int. Cl. H01L 21/762

(52) U.S. Cl. 438/444; 257/E21.553; 257/E21.557

(57) ABSTRACT

An isolation method of active area for semiconductor forms an isolated active area in a substrate. The substrate is a p-type silicon substrate. A pad oxide layer is formed on the substrate. A patterned sacrificial layer and an upper mask layer are formed on the pad oxide layer, where the upper mask layer is formed over the isolation region of the substrate. A gap is formed between the patterned sacrificial layer and the upper mask layer. An implantation process is performed to dope ions into the substrate through the gap, which forms an n-type barrier to surround the active areas. Lastly, the patterned sacrificial layer is stripped, and an anodization process is utilized to convert p-type bulk silicon into porous silicon. Then, an oxidation process is performed to oxidize the porous silicon to form a silicon dioxide isolation region for the active areas.

### RELATED APPLICATIONS

This application claims priority to Taiwan Application Serial Number 96126421, filed Jul. 19, 2007, which is herein incorporated by reference.

### BACKGROUND

1. Field of the Invention

The present invention relates to semiconductor manufacturing techniques. More particularly, the present invention relates to a method of insolating active areas of a semiconductor device.

2. Description of Related Art

Metal-Oxide-Semiconductor (MOS) transistor is a common and fundamental electric device in integrated circuits (ICs). Generally, an IC comprises more than one million MOS transistors. Consequently, adequate isolations are needed between neighboring fundamental devices such as transistors to prevent mutual influences of each other in electric characteristics.

Active areas (AA) are regions of a substrate on which the transistors are located. The conventional method of isolating the neighboring active areas uses trenches, as so-called shallow trench isolation (STI). The shallow trench isolation typically defines trenches between the neighboring active areas. The trenches are filled with dielectric materials to isolate the active areas.

However, when the feature size of the semiconductor device becomes smaller and smaller, filling the dielectric materials into the trenches is more difficult, especially for the trenches with a high aspect ratio. Thus, the manufacturing cost is increased, and the process of filling dielectric materials becomes time-consuming.

Therefore, there is a need to provide an improved isolation method to mitigate or obviate the aforementioned problems.

### SUMMARY

An object of the present invention is to provide an isolation method for active areas of semiconductor devices. The isolation method uses an implantation process to form an n-type barrier surrounding an active area in a substrate. An anodization process is performed to convert a bulk silicon portion inside the n-type barrier into a porous silicon portion. The porous silicon portion is oxidized to form an isolation region. Since the anodization process is an electrochemical reaction, the operating voltages for a p-type silicon substrate and an n-type silicon substrate are obviously different. Thus, the n-type barrier may isolate the active area to prevent the active area from the anodic reaction so as to restrict the growth of the porous silicon portion in a predetermined isolation region. The problems of the conventional shallow trench isolation have been overcome.

An embodiment of an isolation method of active areas of a semiconductor device in accordance with the present invention forms an oxide layer on a substrate where the substrate is a p-type silicon substrate. A patterned sacrificial layer and an upper mask layer are respectively formed on the oxide layer, which defines a gap between the patterned sacrificial layer and the upper mask layer where the upper mask layer is located over an isolation region of the substrate.

An n-type ion implantation process is performed to implant n-type ions into the substrate through the gap to form an n-type barrier around the isolation region in the substrate. The upper mask layer is removed after the n-type ion implantation process. An anodization process is performed to the isolation region to convert a bulk silicon portion of the isolation region into a porous silicon portion. Lastly, the porous silicon portion is oxidized to form a silicon oxide portion such as silicon dioxide.

Another embodiment of an isolation method of active areas of a semiconductor device in accordance with the present invention forms an oxide layer on a substrate where the substrate is a p-type silicon substrate. A patterned sacrificial layer and an upper mask layer are respectively formed on the oxide layer, which defines a gap between the patterned sacrificial layer and the upper mask layer where the upper mask layer is located over an isolation region of the substrate.

An n-type ion implantation process is performed to implant n-type ions into the substrate through the gap to form an n-type barrier around the isolation region in the substrate. The upper mask layer is removed after the n-type ion implantation process. A sidewall layer is formed on a sidewall of the patterned sacrificial layer after the removal of the upper mask layer where the sidewall layer is located over the n-type barrier to shield.

An anodization process is performed to the isolation region to convert a bulk silicon portion of the isolation region into a porous silicon portion. Lastly, the porous silicon portion is oxidized to form a silicon oxide portion such as silicon dioxide.

The embodiments in accordance with the present have advantages as follows.

The isolation method in accordance with the present invention does not have to define the trenches in the substrate and fill the dielectrics into the trenches, i.e. the techniques used by STI method. Thus, the problems of the STI method have been efficiently addressed. Meanwhile, the isolation method in accordance with the present invention reduces manufacturing costs and saves manufacturing time for the semiconductor devices.

### BRIEF DESCRIPTION OF THE DRAWINGS

These and other features, aspects, and advantages of the present invention will become better understood with regard to the following description, appended claims, and accompanying drawings where:

FIG. 1 is a schematic view of a semiconductor device when a step of an embodiment of the isolation method in accordance with the present invention is implemented;

FIG. 2 is a schematic view of the semiconductor device in FIG. 1 when a next treatment of the isolation method is performed;

FIG. 3 is a schematic view of the semiconductor device in FIG. 2 when a next treatment of the isolation method is performed;

FIG. 4 is a schematic view of the semiconductor device in FIG. 3 when a next treatment of the isolation method is performed;

FIG. 5 is a schematic view of the semiconductor device in FIG. 4 when a next treatment of the isolation method is performed;

FIG. 6 is a schematic view of the semiconductor device in FIG. 5 when a next treatment of the isolation method is performed;

FIG. 7 is a schematic view of the semiconductor device in FIG. 6 when a next treatment of the isolation method is performed;

FIG. 8 is a schematic view of the semiconductor device in FIG. 7 when a next treatment of the isolation method is performed;

FIG. 9 is a schematic view of the semiconductor device in FIG. 8 when a next treatment of the isolation method is performed; and

FIG. 10 is a schematic view of the semiconductor device in FIG. 9 when an isolation region is complete in a substrate.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

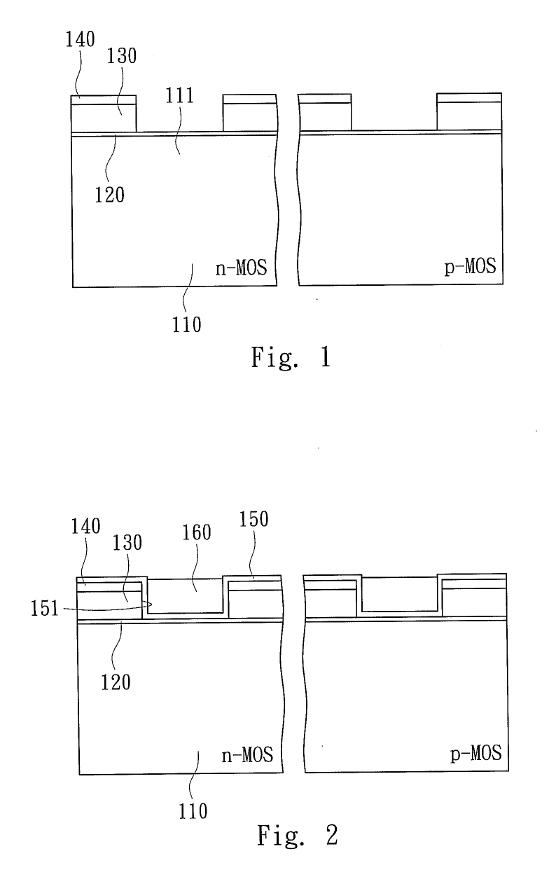

Refer to FIG. 1. An embodiment of an isolation method of active areas of a semiconductor device may be applied to p-MOS and/or n-MOS semiconductor devices. Since an IC may contain both p-MOS and n-MOS devices (such as a CMOS device), the following disclosure provides an exemplary illustration that applies the isolation method for use in both p-MOS and n-MOS devices.

Generally, a MOS device is manufactured on a substrate 110. The substrate 110 may be a p-type silicon substrate (p-Si). A pad oxide layer 120, a first sacrificial layer and a first mask layer are sequentially formed on the substrate 110. The first sacrificial layer and the first mask layer are patterned (may use a photo etching process) so as to form respectively a patterned sacrificial layer 130 and a patterned mask layer 140 and define active areas and isolation regions 111 in the substrate 110. The patterned sacrificial layer 130 may be polysilicon (Poly Si). The patterned mask layer 140 may be a nitride layer.

Refer to FIG. 2. In the embodiment, a second sacrificial layer 150 is formed on the substrate 110 where the second sacrificial layer 150 covers the patterned mask layer 140 and may be a polysilicon layer. Since a portion of the patterned sacrificial layer 130 (i.e. the sidewalls of the patterned sacrificial layer 130) is exposed before the second sacrificial layer 150 is deposited, the exposed portion of the patterned sacrificial layer 130 is oxidized by the oxygen plasma that is used to remove the photoresist defining the active areas. Thus, an oxidized interface 151 is formed between the interface of the second sacrificial layer 150 and the patterned sacrificial layer 130.

A second mask layer is deposited on the second sacrificial layer 150 and is partially etched (etching back) to form an upper mask layer 160. The upper mask layer 160 is formed over the isolation region 111 and may be a nitride layer.

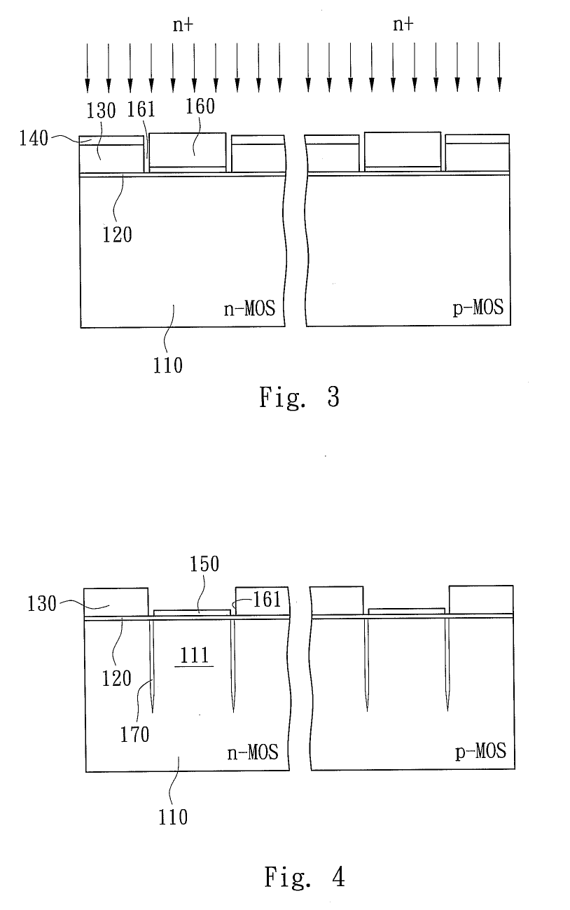

Refer to FIG. 3. Removing the second sacrificial layer 150 by an etching process forms a gap 161 between the upper mask layer 160 and the patterned sacrificial layer 130. An n-type ion implantation process is performed to implant n-type ions into the substrate 110 through the gaps 161. The n-type ions implanted in the substrate 110 form an n-type barrier 170 around the isolation region 111 as shown in FIG. 4.

Refer to FIG. 4. A heat treatment process is performed after the ion implantation process. The heat treatment process may use a rapid thermal anneal (RTA), which enables activations of the implanted n-type ions in the substrate 110 to facilitate distribution of the implanted n-type ions more uniformly. The patterned mask layer 140 and the upper mask layer 160 are removed after the heat treatment process is complete.

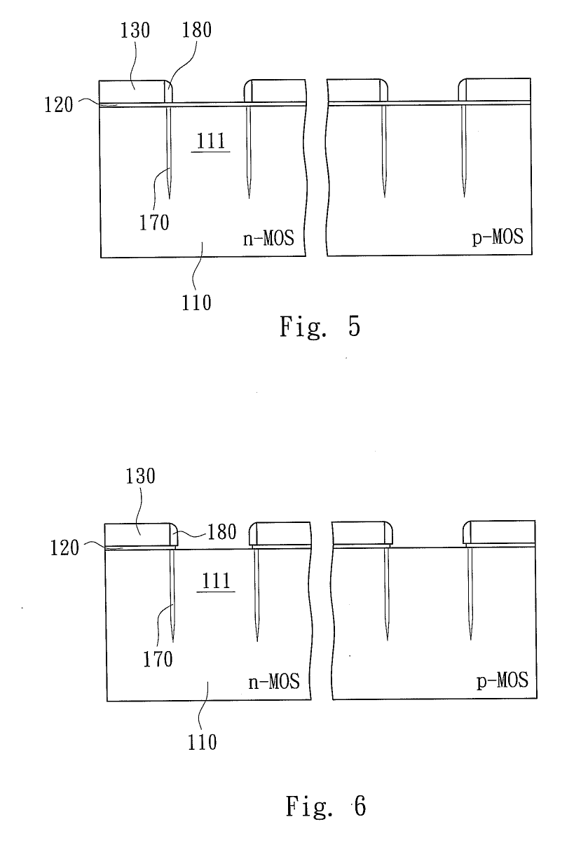

Refer to FIG. 5. Removing the second sacrificial layer 150 by an etching process reveals the pad oxide layer 120 over the isolation region 111. A sidewall layer 180 is formed on the sidewalls of the patterned sacrificial layer 130 after the removal of the mask layers 140,160. The sidewall layer 180 is located over the n-type barrier 170 to shield it. The method of forming the sidewall layer 180 is by depositing a nitride layer on the patterned sacrificial layer 130 and etching partially the nitride layer (etching back). The sidewall layer 180 shields the under n-type barrier 170 being etched by a wet etching during a subsequent anodization process.

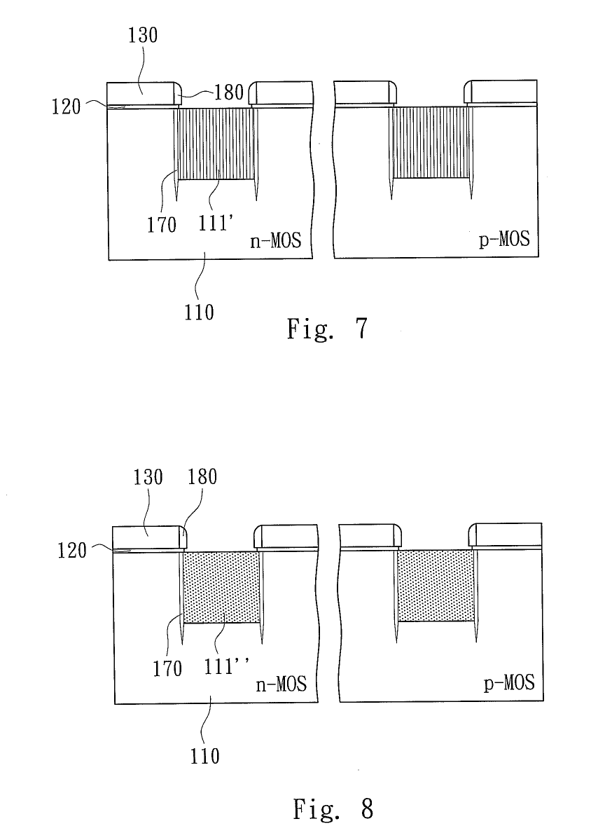

Refer to FIG. 6 and FIG. 7. An anodization process is performed to the isolation region 111 to convert the p-type bulk silicon of the isolation region 111 into porous silicon 111′. A portion of the pad oxide layer 120 over the isolation region 111 is removed to expose the under portion of substrate 110 before the anodization process is performed. Thus, the exposed portion of the substrate 110 can be dealt with the anodization process as shown in FIG. 6. The n-type barrier 170 provides sufficient energy barriers to restrict the growth of porous silicon for the isolation region 111 (i.e. the size of the porous silicon 111′) during the anodization process.

Refer to FIG. 8. An oxidation process is performed to oxidize the porous silicon 111′ to form a silicon dioxide isolation region for the active areas. The oxidation process oxidizes the porous silicon 111′ and converts it into silicon dioxide 111″ (SiO₂). The oxidation process may be a Low-Temperature Wet-Oxidization process.

Refer to FIG. 9. The sidewall layer 180 is removed after the oxidation process. Different subsequent treatments are respectively performed for the n-MOS device and the p-MOS device. For n-MOS device, the use of implanting n-type ions to form the n-type barrier 170 produces over doped effects in the edge of the active areas. Therefore, the implanted n-type ions need to be neutralized by implanting p-type ions. For p-MOS device, the process of implanting p-type ions is not needed.

Hence, a p-type ion implantation process is performed to implant p-type ions into the edge of the active areas and the isolation region 111 for n-MOS devices. Meanwhile, since the semiconductor device contains both the n-MOS device and the p-MOS device, a protecting layer 200 is formed to cover the isolation region 111 of the p-MOS device before the p-type ion implantation process is performed. Since the isolation region 111 of the p-MOS device is shielded by the protecting layer 200, the p-type ions are not implanted into the isolation region 111 of the p-MOS device. The protecting layer 200 may be a photo resist layer.

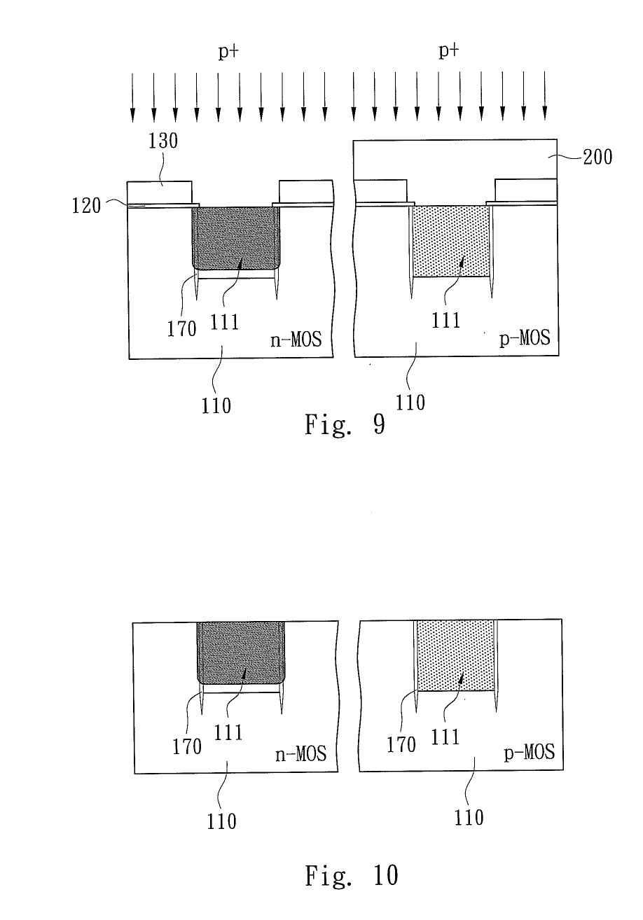

Refer to FIG. 10. The protecting layer 200 is removed after the p-type ion implantation process is complete. A heat treatment process is performed to enable activations of the implanted p-type ions in the substrate 110 to facilitate distribution of the implanted p-type ions more uniformly. The heat treatment process may use a rapid thermal anneal (RTA). The patterned sacrificial layer 130 and the pad oxide 120 are removed after the heat treatment process. Thus, the isolation region 111 that isolates the neighboring active areas for the n-MOS device and/or p-MOS device is manufactured.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An isolation method for use in active areas of a semiconductor device, and the isolation method comprising
providing a substrate where the substrate is a p-type silicon substrate;
forming an oxide layer on the substrate;
forming a patterned sacrificial layer and an upper mask layer on the oxide layer and defining a gap between the patterned sacrificial layer and the upper mask layer where the upper mask layer is located over an isolation region of the substrate;
performing an n-type ion implantation process to implant n-type ions into the substrate through the gap to form an n-type barrier around the isolation region in the substrate;
removing the upper mask layer;
performing an anodization process to the isolation region to convert a bulk silicon portion of the isolation region into a porous silicon portion; and
oxidizing the porous silicon portion to form a silicon dioxide portion.

2. The isolation method as claimed in claim 1, wherein the substrate has an n-MOS device, and after the step of oxidizing the porous silicon portion to form a silicon dioxide portion further comprises
performing a p-type ion implantation process to the isolation region of the n-MOS device; and
performing a heat treatment process, and removing the patterned sacrificial layer and the oxide layer.

3. The isolation method as claimed in claim 1, wherein the substrate has a p-MOS device, and after the step of oxidizing the porous silicon portion to form a silicon dioxide portion further comprises
forming a protecting layer covering the isolation region of the p-MOS device; and
removing the protecting layer, the patterned sacrificial layer and the oxide layer after a p-type ion implantation process.

4. The isolation method as claimed in claim 1, wherein the step of forming a patterned sacrificial layer and an upper mask layer on the oxide layer and defining a gap between the patterned sacrificial layer and the upper mask layer comprises
forming a first sacrificial layer on the substrate;
forming a first mask layer on the first sacrificial layer;
patterning the first mask layer and the first sacrificial layer to form respectively a patterned mask layer and the patterned sacrificial layer;
forming a second sacrificial layer covering the substrate and the patterned mask layer;
forming a second mask layer on the second sacrificial layer and partially etching the second mask layer to form the upper mask layer; and
etching the second sacrificial layer to define the gap between the patterned sacrificial layer and the upper mask layer.

5. The isolation method as claimed in claim 1, wherein the step of removing the upper mask layer comprises
removing simultaneously the upper mask layer and the patterned mask layer; and
removing the second sacrificial layer to reveal the pad oxide layer over the isolation region.

6. The isolation method as claimed in claim 4, wherein the upper mask layer and the patterned mask layer are nitride.

7. The isolation method as claimed in claim 1, wherein the step of oxidizing the porous silicon portion to form a silicon dioxide portion uses a low-temperature wet-oxidization process.

8. The isolation method as claimed in claim 1, wherein after the step of performing an n-type ion implantation process to implant n-type ions into the substrate through the gap to form an n-type barrier around the isolation region in the substrate further comprises
performing a heat treatment process to activate the implanted n-type ions in the substrate.

9. The isolation method as claimed in claim 2, wherein the heat treatment process is a rapid thermal anneal process.

10. The isolation method as claimed in claim 8, wherein the heat treatment process is a rapid thermal anneal process.

11. An isolation method for use in active areas of a semiconductor device, and the isolation method comprising
providing a substrate where the substrate is a p-type silicon substrate;
forming an oxide layer on the substrate;
forming a patterned sacrificial layer and an upper mask layer on the oxide layer and defining a gap between the patterned sacrificial layer and the upper mask layer where the upper mask layer is located over an isolation region of the substrate;
performing an n-type ion implantation process to implant n-type ions into the substrate through the gap to form an n-type barrier around the isolation region in the substrate;
removing the upper mask layer;
forming a sidewall layer on a sidewall of the patterned sacrificial layer where the sidewall layer is located over the n-type barrier;
performing an anodization process to the isolation region to convert a bulk silicon portion of the isolation region into a porous silicon portion; and
oxidizing the porous silicon portion to form a silicon dioxide portion.

12. The isolation method as claimed in claim 11, wherein the sidewall layer is formed by depositing a nitride layer on the patterned sacrificial layer and etching partially the nitride layer.

13. The isolation method as claimed in claim 11, after the step of forming a sidewall layer on a sidewall of the patterned sacrificial layer further comprises removing a portion of the oxide layer over the isolation region.

14. The isolation method as claimed in claim 11, after the step of performing an anodization process to the isolation region to convert a bulk silicon portion of the isolation region into a porous silicon portion further comprises
removing the sidewall layer.

15. The isolation method as claimed in claim 14, wherein the substrate has an n-MOS device, and after the step of removing the sidewall layer further comprising
performing a p-type ion implantation process to the isolation region of the n-MOS device; and
performing a heat treatment process and removing the patterned sacrificial layer and the oxide layer.

16. The isolation method as claimed in claim 14, wherein the substrate has a p-MOS device, and after the step of removing the sidewall layer further comprising
forming a protecting layer covering the isolation region of the p-MOS device; and
removing the protecting layer, the patterned sacrificial layer and the oxide layer after a p-type ion implantation process.

17. The isolation method as claimed in claim 11, wherein the step of forming a patterned sacrificial layer and an upper mask layer on the oxide layer and defining a gap between the patterned sacrificial layer and the upper mask layer comprises
forming a first sacrificial layer on the substrate;
forming a first mask layer on the first sacrificial layer;
patterning the first mask layer and the first sacrificial layer to form respectively a patterned mask layer and the patterned sacrificial layer;
forming a second sacrificial layer covering the substrate and the patterned mask layer;
forming a second mask layer on the second sacrificial layer and partially etching the second mask layer to form the upper mask layer;
etching the second sacrificial layer to define the gap between the patterned sacrificial layer and the upper mask layer; and
removing the second sacrificial layer to reveal the pad oxide layer over the isolation region after the step of removing the upper mask layer.

18. The isolation method as claimed in claim 17, wherein the upper mask layer and the patterned mask layer are nitride.

19. The isolation method as claimed in claim 11, wherein the step of oxidizing the porous silicon portion to form a silicon dioxide portion uses a low-temperature wet-oxidization process.

20. The isolation method as claimed in claim 11, wherein after the step of performing an n-type ion implantation process to implant n-type ions into the substrate through the gap to form an n-type barrier around the isolation region in the substrate further comprises
performing a heat treatment process to activate the implanted n-type ions in the substrate, where the heat treatment process is a rapid thermal anneal process.
